(19) United States
(12) Patent Application Publication
(10) Pub. No.: US 2019/0086157 A1
(43) Pub. Date: Mar. 21, 2019

(54) COOLING SYSTEM, COOLER, AND COOLING METHOD

(71) Applicant: NEC CORPORATION, Tokyo (JP)

(72) Inventors: Masaki CHIBA, Tokyo (JP); Mahiro HACHIYA, Tokyo (JP)

(73) Assignee: NEC CORPORATION, Tokyo (JP)

(21) Appl. No.: 16/081,496

(22) PCT Filed: Feb. 27, 2017
(86) PCT No.: PCT/JP2017/007363

§ 371 Date: Aug. 31, 2018

(30) Foreign Application Priority Data
Mar. 4, 2016 (JP) 2016-042492

(51) Int. Cl. F28D 15/02; H01L 23/427; H05K 7/20

(52) U.S. Cl. CPC F28D 15/02; H05K 7/20; H01L 23/427

(57) ABSTRACT

The cooling system according to the present invention comprises a heat-receiving section including an approximately constant cross-sectional area along a longitudinal direction. The longitudinal direction is a direction in which a length of the heat-receiving section is longest and a direction along an arrangement of the heat source in the cooling region. The cooling system also comprises a supply tube for supplying a refrigerant in a liquid state into the heat-receiving section, and a recovery tube for recovering the refrigerant, which is vaporized upon reception of heat, from an inside of the heat-receiving section. The cooling system further comprises a heat radiation section for cooling the recovered refrigerant and supplying the refrigerant in a liquid state to the supply tube. The heat-receiving section comprises a refrigerant pathway which causes the refrigerant supplied from the supply tube to flow out into the heat-receiving section along the longitudinal direction.

### TECHNICAL FIELD

The present invention relates to a cooling technique for radiating heat by transmitting heat generated from an electronic device or an electronic component by using a cycle of vaporization and condensation of a refrigerant.

### BACKGROUND ART

Miniaturization of an electronic device is advanced by development of process technology and packaging technology for an electronic component such as a semiconductor. Meanwhile, an amount of information to be processed by an electronic device such as an information terminal has been increasing, and thereby an amount of heat generated by an electronic component mounted on an electronic device is increasing.

In the case of air-cooling an electronic component, a large heatsink is required in order to obtain a sufficient air cooling effect. However, in an electronic device with a high packaging density, a space for disposing a heatsink is limited. Accordingly, when some measures are taken, for example, when a wind speed of cooling air is increased, power for an air cooling fan increases, which leads to an increase in operational cost.

In the case of water-cooling an electronic component, a heat-receiving section of a cooler can be installed in an electronic component and a heat radiation section of the cooler can be installed in a location apart from the electronic component, and therefore, a space required for cooling in the electronic device is smaller than that for air cooling. Further, PTLs 1 and 2 disclose a cooler in which a fin structure is provided in a heat-receiving section in order to improve thermal conductivity to a refrigerant. Furthermore, PTL 3 discloses a cooler capable of allowing a temperature to rise slowly when supply of a refrigerant is interrupted.

However, in water cooling as described above, when a large number of electronic components being heat sources are present, a temperature of a refrigerant increases, and thereby a cooling efficiency of the electronic components located at a downstream side of the refrigerant deteriorates. Accordingly, when measures for increasing power of a pump to increase a flow rate of the refrigerant are taken, an operational cost increases. Further, when the flow rate of the refrigerant is increased, pressure of a cooling system increases and a risk of leakage of the refrigerant increases.

PTL 4 discloses a cooling device using phase-change cooling for heat radiation by transmitting heat generated from an electronic component by using a cycle of vaporization and condensation of a refrigerant. According to PTL 4, a plurality of heat receivers to be respectively brought into contact with a plurality of electronic components being heat sources are connected in series, and a check valve is installed at a refrigerant inflow port of a heat receiver in an uppermost stream portion. Each heat receiver removes heat from the heat source as latent heat when the refrigerant is vaporized. A temperature of the refrigerant in the heat receiver at this time is determined by a saturated vapor temperature unambiguously defined by saturated vapor pressure of the refrigerant. Accordingly, the temperature of the refrigerant is substantially constant during occurrence of a phase change. Thus, it is described that a small cooling device capable of dealing with a large amount of heat generation is achieved without requiring any drive power for refrigerant circulation.

PTL 5 also discloses a technique relating to a cooling device using phase-change cooling. According to PTL 5, in a process of a boiling phenomenon of a refrigerant due to absorption of heat from a heat source, ebullient cooling by nuclear boiling in a temperature region in which transition boiling may occur can be achieved for a larger cooling area. Thus, it is described that an efficiency of phase-change cooling is improved.

### CITATION LIST

### Patent Literature

[PTL 1] International Patent Publication No. WO 2012/157247
[PTL 2] International Patent Publication No. WO 2011/004815
[PTL 3] Japanese Unexamined Patent Application Publication No. 2014-220452
[PTL 4] Japanese Unexamined Patent Application Publication No. 2014-116385
[PTL 5] Japanese Unexamined Patent Application Publication No. 2007-150216

### SUMMARY OF INVENTION

### Technical Problem

However, even when phase-change cooling is used in the cooling device disclosed in PTL 4, a difference in cooling effect occurs between a heat-receiving section at the upstream side of the refrigerant and a heat-receiving section at the downstream side of the refrigerant.

This is because internal pressure in a heat-receiving section at the upstream side is different from that in a heat-receiving section at the downstream side. Specifically, a pressure in each heat-receiving section is a pressure obtained by adding a pressure loss from the heat radiation section to each heat-receiving section to a pressure determined by a condensation temperature in the heat radiation section. A pressure in a heat-receiving section at the lowermost stream side is a pressure obtained by adding a pressure loss in a pipe from the heat-receiving section to the heat radiation section, to a pressure in the heat radiation section. A pressure in a heat-receiving section at the uppermost stream side is a pressure obtained by adding a pressure loss generated in a pipe and all heat-receiving sections from the uppermost stream heat-receiving section to the heat radiation section, to a pressure in the heat radiation section. Further, since the heat-receiving section has a structure for increasing a heat transfer area, a pressure loss in the heat-receiving section is larger than that in a simple pipe. Accordingly, a pressure in a heat-receiving section at the upstream side is larger than in that at the downstream side, and a boiling point increases. As a result, a temperature of a heat source easily increases.

On the other hand, a liquid refrigerant that is supercooled to a temperature lower than the boiling point due to condensation in the heat radiation section flows into the uppermost stream heat-receiving section. Accordingly, a part of an amount of heat from a heat source is used as sensible heat corresponding to a heat capacity for allowing the liquid refrigerant to reach the boiling point, and an amount of heat to be absorbed into the refrigerant as vaporization heat decreases. As a result, in the uppermost stream heat-receiving section, a temperature rise from the boiling point of a heat source is smaller than that in other heat-receiving sections. However, the supercooled refrigerant does not reach a second and subsequent heat-receiving sections from the uppermost stream, and thereby there is no contribution of sensible heat.

As described above, in the cooling device disclosed in PTL 4, deterioration in cooling effect at the downstream side, which involves a problem during water cooling, is suppressed. On the contrary, there is a problem that the cooling effect at the upstream side easily deteriorates. Further, the cooling devices disclosed in PTL 4 and PTL 5 neither disclose nor suggest the problem and a solution to the problem.

The present invention has been made in view of the above-described problem, and an object of the present invention is to provide a cooling system capable of efficient cooling even a plurality of electronic components which are packaged with a high density and have a large amount of heat generation, without requiring any drive source for a refrigerant.

### Solution to Problem

A cooling system according to the present invention comprises a heat-receiving section including a cooling region for cooling a heat source. The heat-receiving section comprises an approximately constant cross-sectional area along a longitudinal direction. The longitudinal direction is a direction in which a length of the heat-receiving section is longest and a direction along an arrangement of the heat source in the cooling region. The cooling system also comprises a supply tube for supplying a refrigerant in a liquid state into the heat-receiving section, and a recovery tube for recovering the refrigerant, which is vaporized upon reception of heat, from an inside of the heat-receiving section. The cooling system also comprises a heat radiation section for cooling the recovered refrigerant and supplying the refrigerant in a liquid state to the supply tube. The heat-receiving section comprises a refrigerant pathway which causes the refrigerant supplied from the supply tube to flow out into the heat-receiving section along the longitudinal direction.

A cooler according to the present invention comprises a heat-receiving section including a cooling region for cooling a heat source. The heat-receiving section comprises an approximately constant cross-sectional area along a longitudinal direction. The longitudinal direction is a direction in which a length of the heat-receiving section is longest and a direction along an arrangement of the heat source in the cooling region. The cooler comprises a refrigerant which is supplied in a liquid state into the heat-receiving section, is vaporized upon reception of heat, and is recovered from an inside of the heat-receiving section, and a refrigerant pathway which causes the refrigerant supplied in a liquid state to flow out into the heat-receiving section along the longitudinal direction.

A cooling method according to the present invention comprises causing a refrigerant being supplied in a liquid state to a heat-receiving section including an approximately constant cross-sectional area along a longitudinal direction, to flow out into the heat-receiving section along the longitudinal direction of the heat-receiving section. The longitudinal direction is a direction in which a length of the heat-receiving section is longest and a direction along an arrangement of the heat source in the cooling region. The cooling method also comprises recovering the refrigerant, which is vaporized when the heat-receiving section receives heat, from an inside of the heat-receiving section, and cooling the recovered refrigerant and supplying the refrigerant in a liquid state to the heat-receiving section.

### Advantageous Effects of Invention

According to the present invention, it is possible to provide a cooling system capable of efficiently cooling even a plurality of electronic components, which are packaged with a high density and have a large amount of heat generation, without requiring any drive source for a refrigerant.

### BRIEF DESCRIPTION OF DRAWINGS

FIG. 1 is a diagram illustrating a configuration of a cooling system according to a first example embodiment of the present invention;

FIG. 2 is a diagram illustrating a configuration of a cooling system according to a second example embodiment of the present invention;

FIG. 3 is a sectional view illustrating the configuration of a heat-receiving section of the cooling system according to the second example embodiment of the present invention;

FIG. 4 is a sectional view illustrating the configuration of the heat-receiving section of the cooling system according to the second example embodiment of the present invention;

FIG. 5 is a sectional view illustrating a configuration of a heat-receiving section of a cooling system according to a third example embodiment of the present invention;

FIG. 6 is a sectional view illustrating the configuration of the heat-receiving section of the cooling system according to the third example embodiment of the present invention;

FIG. 7 is a diagram illustrating a configuration of a liquid tube in the heat-receiving section of the cooling system according to the third example embodiment of the present invention;

FIG. 8 is a diagram illustrating a configuration of another liquid tube in the heat-receiving section of the cooling system according to the third example embodiment of the present invention; and

FIG. 9 is a diagram illustrating a configuration of still another liquid tube in the heat-receiving section of the cooling system according to the third example embodiment of the present invention.

### EXAMPLE EMBODIMENT

Hereinafter, example embodiments of the present invention will be described in detail with reference to the drawings. However, limitations technically preferable to carry out the present invention are imposed on the example embodiments described below, but do not limit the scope of the invention to the followings.

### First Example Embodiment

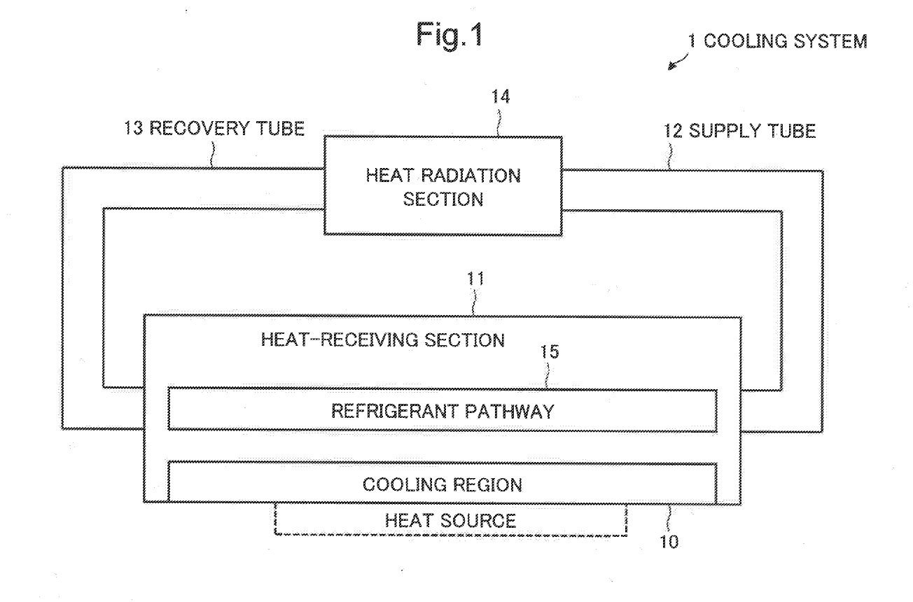

FIG. 1 is a diagram illustrating a configuration of a cooling system according to a first example embodiment of the present invention. A cooling system 1 comprises a heat-receiving section 11 including a cooling region 10 for cooling a heat source. The heat-receiving section 11 comprises an approximately constant cross-sectional area along a longitudinal direction. The longitudinal direction is a direction in which a length of the heat-receiving section 11 is longest and a direction along an arrangement of the heat source in the cooling region 10. Further, the cooling system 1 comprises a supply tube 12 for supplying a refrigerant in a liquid state into the heat-receiving section 11, and a recovery tube 13 for recovering the refrigerant, which is vaporized upon reception of heat, from an inside of the heat-receiving section 11. Further, the cooling system 1 comprises a heat radiation section 14 for cooling the recovered refrigerant and supplying the refrigerant in a liquid state to the supply tube 12. Further, the heat-receiving section 11 comprises a refrigerant pathway 15 which causes the refrigerant supplied from the supply tube 12 to flow out into the heat-receiving section 11 along the longitudinal direction.

According to the cooling system 1, the refrigerant supplied into the heat-receiving section 11 from the supply tube 12 is approximately equally distributed to an upstream side and a downstream side of the refrigerant. In addition, an increase in pressure at the upstream side is prevented, so that the same cooling effect at the upstream side and the downstream side of the heat-receiving section 11 is achieved.

As described above, according to the present example embodiment, it is possible to provide a cooling system capable of efficiently cooling even a plurality of electronic components, which are packaged with a high density and have a large amount of heat generation, without requiring any drive source for a refrigerant.

### Second Example Embodiment

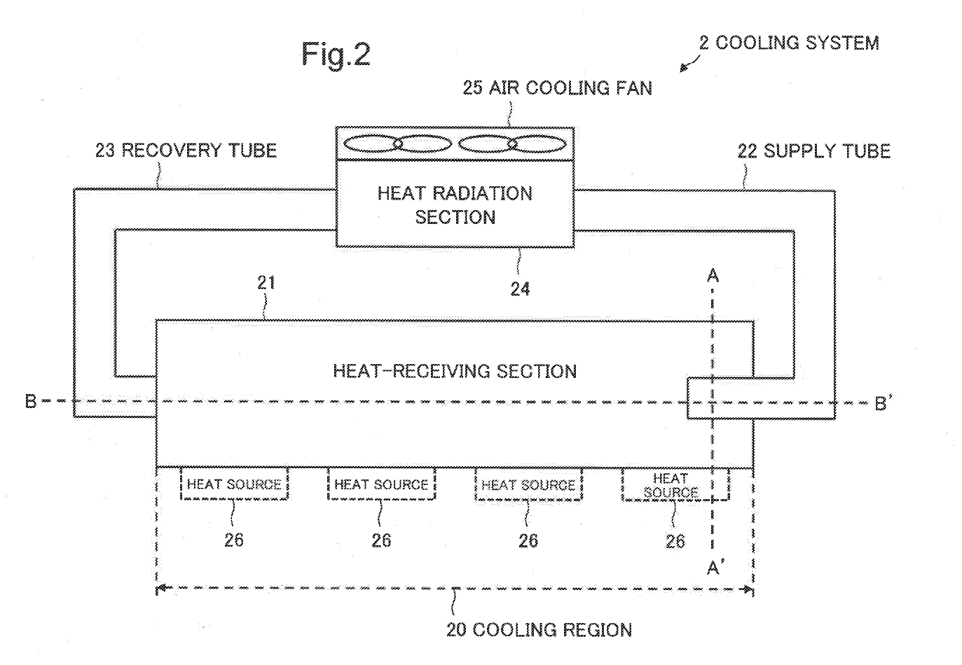

FIG. 2 is a diagram illustrating a configuration of a cooling system according to a second example embodiment of the present invention. A cooling system 2 comprises a heat-receiving section 21, a supply tube 22, a recovery tube 23, and a heat radiation section 24. The cooling system 2 is capable of cooling heat generated by electronic components which are a plurality of heat sources 26 by using the principle of thermosiphon. Examples of the electronic components comprise a semiconductor device, a transformer, and a small motor, but the electronic components are not limited to these examples. Although FIG. 2 illustrates four of the heat sources 26, the number of the heat sources is not limited to four.

The heat-receiving section 21 comprises a cooling region 20 for cooling the heat sources 26 by receiving heat generated by the heat sources 26. Further, the heat-receiving section 21 comprises an approximately constant cross-sectional area along a longitudinal direction. The longitudinal direction is a direction along an arrangement of the heat sources 26 of the cooling region 20 and a direction in which a length of the heat-receiving section 21 is longest. The supply tube 22 supplies a refrigerant for phase-change cooling in a liquid state into the heat-receiving section 21. Further, the heat-receiving section 21 comprises a refrigerant pathway which is provided within the heat-receiving section 21 along the longitudinal direction and causes the refrigerant supplied from the supply tube 22 to approximately equally flow out into the heat-receiving section 21 along the longitudinal direction. The heat-receiving section 21 will be described in detail below.

The recovery tube 23 recovers the refrigerant, which is vaporized when the heat-receiving section 21 receives heat, into the heat radiation section 24 from an inside of the heat-receiving section 21. The heat radiation section 24 is installed in a location apart from the heat sources 26. The heat radiation section 24 may be a fin-and-tube radiator, but is not limited to this. The heat radiation section 24 illustrated in FIG. 2 is provided with an air cooling fan 25 and has a structure for heat radiation by cooling air generated by the air cooling fan 25. Further, the heat radiation section 24 is connected to the supply tube 22.

An internal space formed by the heat-receiving section 21, the recovery tube 23, the heat radiation section 24, and the supply tube 22 is sealed, and a low boiling point refrigerant for phase-change cooling is encapsulated in the internal space. Further, this internal space is filled with refrigerant liquid and saturated vapor.

Heat generated by the heat sources 26 is absorbed as latent heat into the refrigerant encapsulated in the heat-receiving section 21 in the cooling region 20 of the heat-receiving section 21. Thus, the heat sources 26 are cooled. On the other hand, vapor of the refrigerant generated due to the absorption of heat in the heat-receiving section 21 flows into the heat radiation section 24 through the recovery tube 23. In the heat radiation section 24, heat is exchanged between the refrigerant vapor and cooling air passing through the radiator by the air cooling fan 25, and the refrigerant vapor is cooled and condensed into liquid. The liquid refrigerant is supplied to the heat-receiving section 21 again through the supply tube 22.

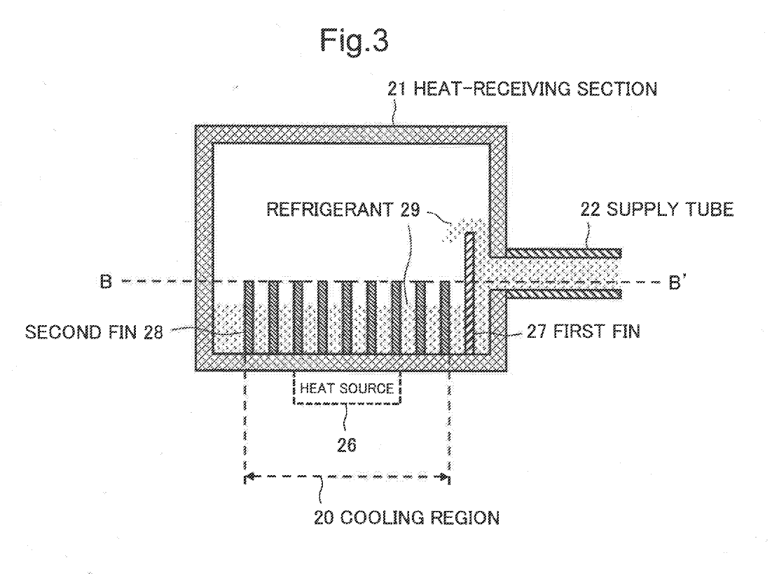

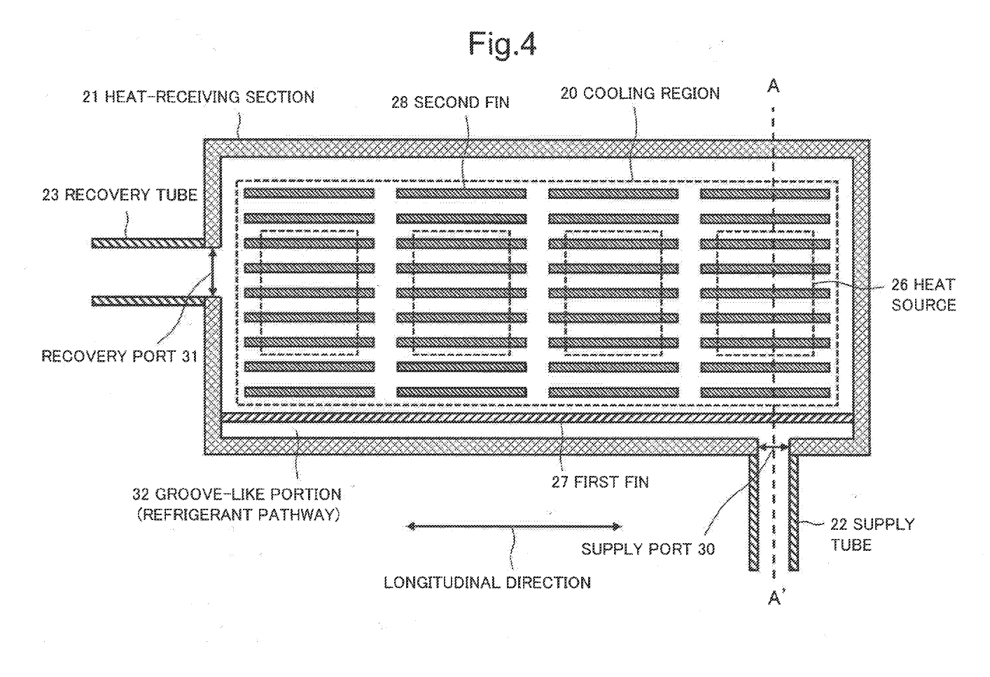

FIG. 3 is a sectional view (section taken along a line A-A′ in FIG. 2) illustrating the configuration of the heat-receiving section 21 of the cooling system 2. FIG. 4 is a sectional view (section taken along a line B-B′ in FIG. 2) illustrating the configuration of the heat-receiving section 21 of the cooling system 2. Note that in FIG. 4, an illustration of the refrigerant is omitted.

The cooling region 20 of the heat-receiving section 21 is in contact with the plurality of heat sources 26 in such a way as to cover each of the heat sources 26. The cooling region 20 is a region for allowing the heat sources 26 to be contacted. In the case of the heat-receiving section 21, the cooling region 20 corresponds to a bottom surface of the heat-receiving section. In the bottom surface, a portion opposed to the refrigerant pathway may be disposed outside of the cooling region 20. The cooling region 20 may be provided in a distinguished manner in the bottom surface. For example, in the case of the heat-receiving section 21, as illustrated in FIGS. 3 and 4, a region which corresponds to bottom surfaces of four regions each provided with second fins 28 to be described below and which surrounds the four regions may be set as the cooling region 20.

The heat-receiving section 21 includes an approximately constant cross-sectional area along a longitudinal direction. The longitudinal direction is a direction along the arrangement of the heat sources 26 in the cooling region 20 and a direction in which the length of the heat-receiving section 21 is longest. The cross-sectional area described herein refers to the area of a cross-section of the inner periphery of the heat-receiving section 21. As illustrated in FIG. 4, the longitudinal direction corresponds to a direction in which the heat sources 26 are arranged. The heat-receiving section 21 has the cross-section of the inner periphery made into an approximately constant cross-sectional shape along the longitudinal direction, thereby achieving the approximately constant cross-sectional area.

The term “approximately constant” means the cross-sectional area is constant such that deviation of the cross-sectional area does not cause a deviation of a pressure which affects boiling of the refrigerant when the refrigerant vapor is recovered from a recovery port 31. Consequently, this configuration prevents generating a portion in which the cooling effect is lowered in the cooling region 20 of the heat-receiving section 21. Accordingly, in the cooling system 2 according to the present example embodiment, it is preferable to set a constant cross-sectional area, and it is also preferable to set an approximately constant cross-sectional area.

The cross-sectional shape of the heat-receiving section 21 is a rectangular shape as illustrated in FIG. 3, but is not limited to this shape. The cross-sectional shape may be a polygonal shape such as a triangle or a pentagon, or a composite shape, such as a semi-cylindrical shape, which includes a linear portion and a curve portion. The cross-sectional shape may also be a shape having a protrusion at a part of the outer periphery.

The heat-receiving section 21 includes a first fin 27 formed therein. The first fin 27 is embedded in a bottom surface within the heat-receiving section 21 along the longitudinal direction, is in close contact with wall surfaces at both ends in the longitudinal direction within the heat-receiving section 21, and has a uniform height with a gap being opened between the first fin and a ceiling within the heat-receiving section 21. A groove-like portion 32 which is formed between the first fin 27 and one side surface in the longitudinal direction within the heat-receiving section 21. the groove-like portion 32 serves as a refrigerant pathway for a liquid refrigerant 29 to be supplied by the supply tube 22 through a supply port 30 which is provided in the heat-receiving section 21. In FIG. 4, the supply port 30 is provided in the side surface on a side of the first fin 27 in the longitudinal direction within the heat-receiving section 21. However, the supply port 30 is not limited to this configuration. The supply port 30 may be provided in such a way that the liquid refrigerant 29 can be supplied to the groove-like portion 32.

Flow of the refrigerant 29 supplied to the heat-receiving section 21 from the supply port 30 is dammed by the first fin 27. The first fin 27 has no groove or the like formed therein, and is in close contact with wall surfaces at both ends in the longitudinal direction. Accordingly, when the refrigerant 29 does not exceed the height of the first fin 27, the refrigerant 29 remains in the groove-like portion 32 and does not flow out into the cooling region 20 side. When a liquid level of the refrigerant 29 exceeds the height of the first fin 27, the refrigerant 29 approximately equally flows out toward the cooling region 20 side.

Thus, the refrigerant 29 which is supercooled to a temperature lower than the boiling point due to condensation in the heat radiation section 24 is approximately equally supplied to the plurality of heat sources 26. Accordingly, a part of the amount of heat generated by each heat source 26 is absorbed into the refrigerant 29 as sensible heat for liquid temperature increase, so that an increase in temperature from the boiling point of the refrigerant 29 can be suppressed. Specifically, each heat source 26 enables efficient and approximately equal cooling even at the upstream side or the downstream side with respect to the supply port 30 through which the refrigerant 29 is supplied. Note that the liquid level of the refrigerant 29 flowing out toward the cooling region 20 side during a cooling operation is set to be lower than the height of the first fin 27.

Note that the term “approximately equally” herein when the respective heat sources 26 are approximately equally cooled by the refrigerant 29 may indicate that electronic components serving as heat sources are equally cooled within a range. The range indicates such an extent that the electronic components can normally perform their respective operations. Thus the term “approximately equally” indicates the equality which allows a variation within the range. Accordingly, in the cooling system 2 according to the present example embodiment, it is preferable to equally supply the refrigerant, and it is also preferable to approximately equally supply the refrigerant.

The heat-receiving section 21 can be provided with the second fins 28 formed therein. The second fins 28 are embedded in the bottom surface within the heat-receiving section 21 along the longitudinal direction. As illustrated in FIG. 4, the second fins 28 can be provided for each heat source 26. The second fins 28 allow the heat-receiving section 21 to efficiently transmit heat from the heat sources 26 to the refrigerant 29. As illustrated in FIGS. 3 and 4, the second fins 28 may be set with the same height, the same thickness, and the same length. However, the configuration of each second fin 28 is not limited to this configuration. The second fins 28 can be appropriately designed depending on features of each heat source 26, such as a dimension and an amount of heat generation. Further, the cooling region 20 may be a region which surrounds the second fins 28 in the bottom surface in which the second fins 28 are provided.

The liquid refrigerant 29 is changed into refrigerant vapor using the heat received from the heat sources 26 as vaporization heat and flows toward the recovery port 31. In this case, the inside of the heat-receiving section 21 includes an approximately constant cross-sectional area along the longitudinal direction. The longitudinal direction is a direction in which the length of the cooling region 20 is longest and along the arrangement of the heat sources 26. Accordingly, the refrigerant vapor within the heat-receiving section 21 does not receive a pressure loss due to rapid expansion, compression, or the like during the movement of the refrigerant vapor. Further, the refrigerant vapor can move through a gap formed between the second fins 28 and the ceiling without any obstruction due to the gap. Therefore, even the refrigerant vapor generated at the upstream side can move toward the recovery port 31 while receiving approximately no pressure loss. Consequently, the cooling system 2 prevents a deterioration in cooling effect due to an increase in pressure of the refrigerant vapor at the upstream side of the refrigerant while phase-change cooling performed in series with respect to the plurality of heat sources.

As described above, in the heat-receiving section 21, the supercooled liquid refrigerant 29 is approximately equally supplied to the plurality of heat sources 26. And the refrigerant vapor which is vaporized by the absorption of heat from the respective heat sources 26 receives approximately no pressure loss. Thus, the recovery port 31 for recovering the refrigerant vapor can be provided at any position within a range which cause no influence on the cooling effect. The influence is, for example, that the recovery port 31 cause the liquid refrigerant to flow out within the heat-receiving section 21.

The shape of the heat-receiving section 21 having a constant cross-sectional shape along the longitudinal direction can be manufactured by injection molding using an extruded material which is injected along the longitudinal direction. Accordingly, the length of the heat-receiving section in the longitudinal direction can be easily changed, as needed, and the heat-receiving section can be manufactured with high versatility and low cost. Further, the injection molding can reduce a cost compare with manufacturing a structure by connecting a plurality of heat-receiving sections, because the injection molding does not need connecting cost.

As described above, according to the cooling system 2, the refrigerant supplied into the heat-receiving section 21 from the supply tube 22 is approximately equally distributed to the upstream side and the downstream side. Further, approximately same cooling effect is obtained at the upstream side and the downstream side of the heat-receiving section 21 because an increase in pressure at the upstream side is prevented.

As described above, according to the present example embodiment, it is possible to provide a cooling system capable of efficiently cooling even a plurality of electronic components which are packaged with a high density and have a large amount of heat generation, without requiring any drive source for a refrigerant.

### Third Example Embodiment

A cooling system according to a third example embodiment of the present invention differs from the cooling system 2 of the second example embodiment in which comprises a liquid tube. The liquid tube forms a refrigerant pathway. On the contrary, the refrigerant pathway of the second example embodiment is the groove-like portion 32 formed by the first fin 27 in the heat-receiving section 21 in the cooling system 2. Other portions in the cooling system according to the present example embodiment are similar to those in the cooling system 2 according to the second example embodiment, and thus descriptions of overlapping portions are omitted.

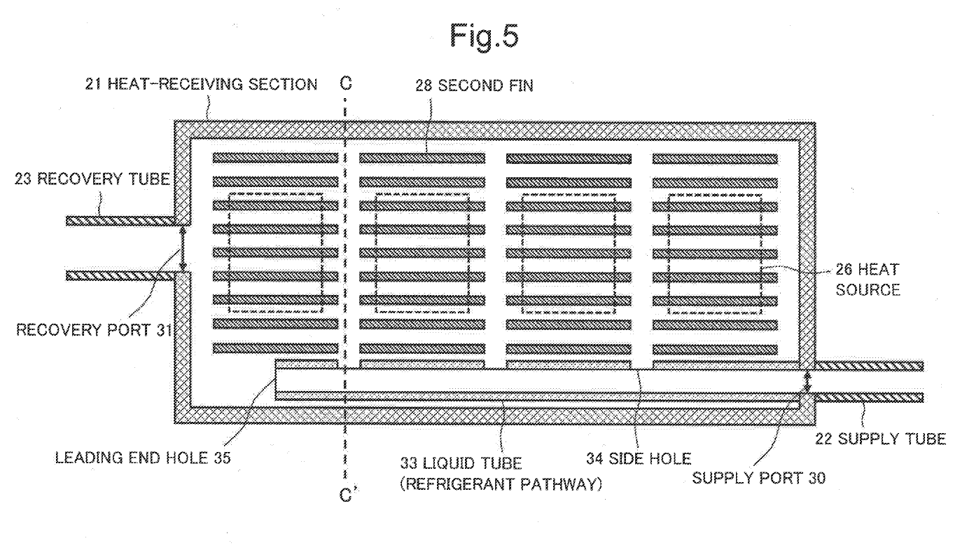

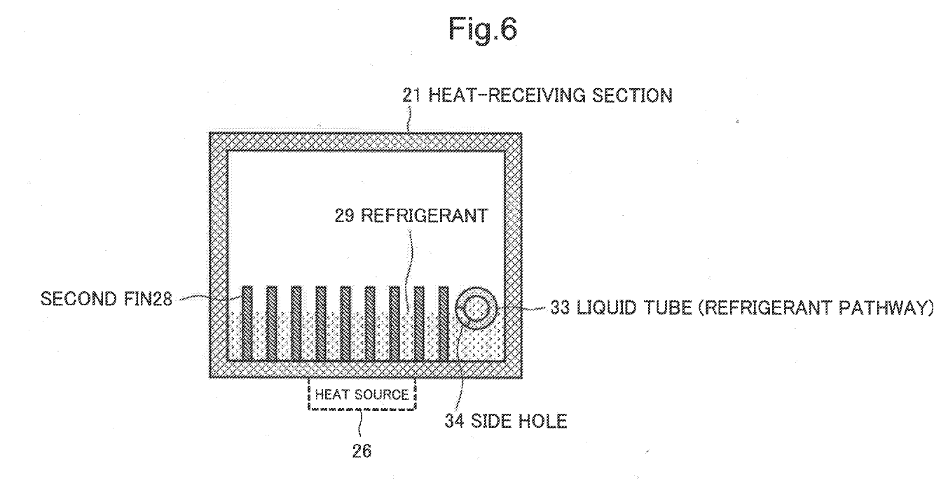

FIG. 5 is a sectional view (corresponding to FIG. 4 of the second example embodiment) illustrating a configuration of a heat-receiving section 21 in the cooling system according to the present example embodiment. FIG. 6 is a sectional view (section taken along a line C-C′ in FIG. 5) illustrating the configuration of the heat-receiving section 21 in the cooling system. Note that in FIG. 5, illustration of a refrigerant is omitted.

The heat-receiving section 21 comprises a liquid tube 33 as a refrigerant pathway in the heat-receiving section 21. The liquid tube 33 is connected to a supply tube 22 through a supply port 30 provided in the heat-receiving section 21. The liquid tube 33 is provided at a position apart from a bottom surface of the heat-receiving section 21 which is in contact with heat sources 26. The position prevents the liquid tube 33 from direct receiving the heat generated by the heat sources 26. The liquid tube 33 extends in the longitudinal direction in the heat-receiving section 21.

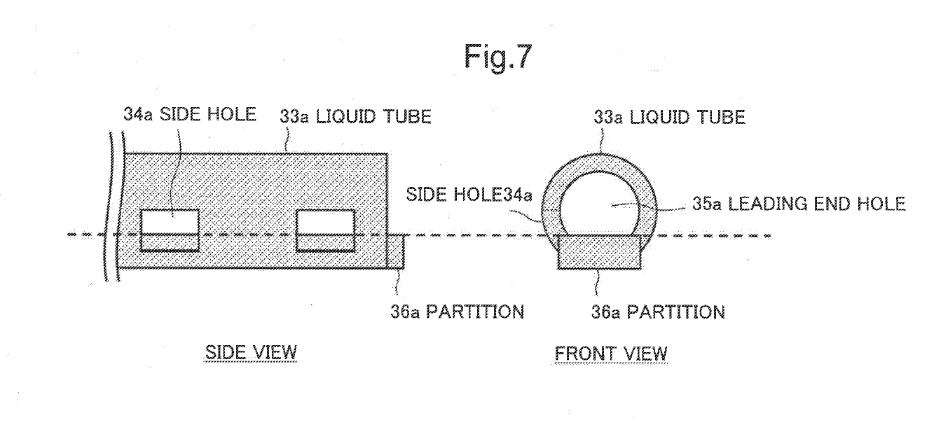

The liquid tube 33 comprises side holes 34 and a leading end hole 35 for distributing a liquid refrigerant supplied from the supply tube 22 so as to cool the respective heat sources 26. The side holes 34 and the leading end hole 35 are provided in such a manner that the refrigerant is approximately equally distributed to the respective heat sources 26. Details of this configuration will be described below with reference to FIGS. 7, 8, and 9. In the structures illustrated in FIGS. 7, 8, and 9, the liquid tube 33 enables approximately equal distribution of the refrigerant to the respective heat sources 26.

Second fins 28 which are provided in order to efficiently transmit heat from the respective heat sources 26 to the refrigerant are preferably provided so as not to inhibit the flow of the refrigerant flowing out from the side holes 34. For example, the second fins 28 are provided at positions other than the positions opposed to the side holes 34.

FIG. 7 is a diagram illustrating a configuration of a liquid tube 33ain the heat-receiving section 21 of the cooling system according to the present example embodiment. In the configuration of FIG. 7, side holes 34a are provided in a side surface (a left side surface in the front view of FIG. 7) of the liquid tube 33a. Further, a partition 36a is disposed at leading end hole 35a. The partition 36a has a height at which the side holes 34a are located at the inner wall of the liquid tube 33a. With this configuration, when a liquid level of the refrigerant flowing into the liquid tube 33a from the supply tube 22 reaches the side holes 34a and the leading end hole 35a partitioned by the partition 36a. Then the refrigerant is allowed to flow out into the heat-receiving section 21 simultaneously from the side holes 34a and the leading end hole 35a.

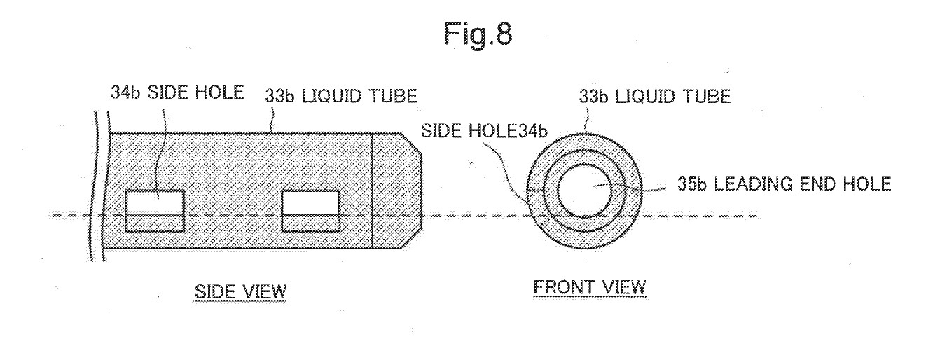

FIG. 8 is a diagram illustrating another configuration of the liquid tube in the heat-receiving section 21 of the cooling system according to the present example embodiment. In the configuration of FIG. 8, side holes 34b are similar to those illustrated in FIG. 7. In a portion at a leading end hole 35b, the leading end is tapered. The tapered leading end gives a similar effect to the partition 36a illustrated in FIG. 7. This configuration enables the refrigerant in a liquid tube 33b to flow out into the heat-receiving section 21 simultaneously from the side holes 34b and the leading end hole 35b.

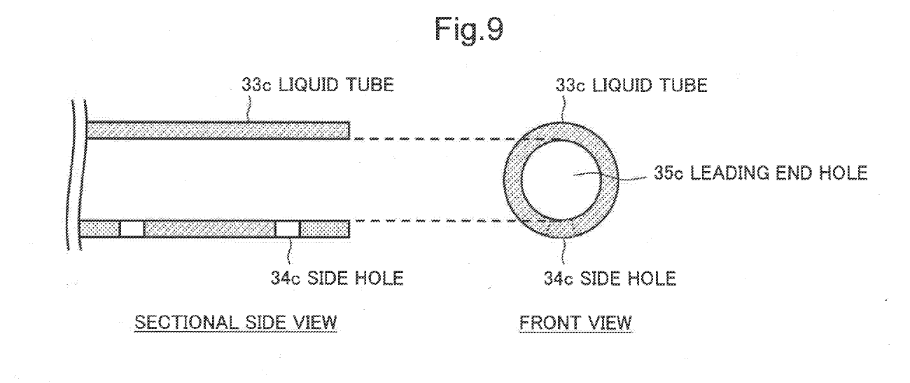

FIG. 9 is a diagram illustrating still another configuration of the liquid tube in the heat-receiving section 21 of the cooling system according to the present example embodiment. In the configuration of FIG. 9, side holes 34c are provided in a lower portion (a lower side surface in the front view of FIG. 9) of a liquid tube 33c, the size and density of the side holes 34c and the size of a leading end hole 35c are adjusted. Thus, the refrigerant is allowed to flow out from the respective side holes 34c and the leading end hole 35c. The refrigerant flow out from the side hole 34c which is close to the supply port 30 at an initial stage, then the refrigerant flow out simultaneously from the respective side holes 34c and the leading end hole 35c at a stationary stage.

The structures illustrated in FIGS. 7, 8, and 9 described above enable the liquid tube 33 to approximately equally distribute the refrigerant to the respective heat sources 26. In other words, in FIGS. 7 to 9, the number, dimensions, and position of the side holes can be arbitrarily adjusted depending on the number of heat sources, the amount of heat generation, or the like. For example, the refrigerant may be supplied only from the leading end hole 35, or may be supplied only from the side holes 34, as long as the refrigerant can be approximately equally supplied to the respective heat sources 26.

Note that the refrigerant pathway is not limited to the groove-like portion 32 or the liquid tube 33. These refrigerant pathways has function that flow out the liquid state refrigerant supplied from the supply tube 22 approximately equally into the heat-receiving section 21 along the longitudinal direction of the heat-receiving section 21. The refrigerant pathway may be an element which has that function. The location where the refrigerant pathway is provided is not limited to the inside of the heat-receiving section 21. The refrigerant pathway may be provided outside the heat-receiving section 21.

As described above, according to the cooling system of the present example embodiment, the refrigerant supplied into the heat-receiving section 21 from the supply tube 22 is approximately equally distributed to the upstream side and the downstream side. Further an increase in pressure at the upstream side is suppressed. Thereby the cooling system realize the same cooling effect at the upstream side and the downstream side of the heat-receiving section 21.

As described above, according to the present example embodiment, it is possible to provide a cooling system capable of efficiently cooling even a plurality of electronic components. It is possible to provide the cooling system even the electronic components are packaged with a high density and have a large amount of heat generation, without requiring any drive source for a refrigerant.

While the present invention has been described above with reference to the example embodiments, the present invention is not limited to the example embodiments described above. The configuration and details of the present invention can be modified in various ways that can be understood by those skilled in the art within the scope of the present invention.

The whole or part of the example embodiments described above can also be described as, but not limited to, the following supplementary notes.

### (Supplementary Note 1)

A cooling system comprising:

a heat-receiving section including an approximately constant cross-sectional area along a longitudinal direction in which a length of a cooling region along an arrangement of a heat source is longest, the cooling region cooling the heat source;

a supply tube for supplying a refrigerant in a liquid state into the heat-receiving section;

a recovery tube for recovering the refrigerant from an inside of the heat-receiving section, the refrigerant being vaporized upon reception of heat; and

a heat radiation section for cooling the recovered refrigerant and supplying the refrigerant in a liquid state to the supply tube, in which

the heat-receiving section comprises a refrigerant pathway which causes the refrigerant supplied from the supply tube to flow out into the heat-receiving section along the longitudinal direction.

### (Supplementary Note 2)

The cooling system according to Supplementary note 1, in which the heat-receiving section comprises the approximately constant cross-sectional area with an approximately constant cross-sectional shape.

### (Supplementary Note 3)

The cooling system according to Supplementary note 1 or 2, in which the refrigerant pathway comprises a groove-like portion formed between a first fin and one side surface in the longitudinal direction within the heat-receiving section, the first fin being embedded in a bottom surface within the heat-receiving section along the longitudinal direction, being in close contact with wall surfaces at both ends in the longitudinal direction within the heat-receiving section, and having a uniform height with a gap being opened between the first fin and a ceiling within the heat-receiving section.

### (Supplementary Note 4)

The cooling system according to Supplementary note 3, in which the first fin is higher than a liquid level of the refrigerant flowing out into the heat-receiving section.

### (Supplementary Note 5)

The cooling system according to Supplementary note 1 or 2, in which the refrigerant pathway comprises a tube which extends in the longitudinal direction, causes the refrigerant to flow in from one end of the heat-receiving section, causes the refrigerant to flow into the heat-receiving section from a plurality of side holes provided at an outer peripheral surface and a leading end hole provided at another end of the heat-receiving section, and is provided at a position apart from a bottom surface within the heat-receiving section.

### (Supplementary Note 6)

The cooling system according to any one of Supplementary notes 1 to 5, in which the refrigerant pathway causes the refrigerant to approximately equally flow out into the heat-receiving section along the longitudinal direction.

### (Supplementary Note 7)

The cooling system according to any one of Supplementary notes 1 to 6, in which the heat-receiving section comprises a second fin which is embedded in a bottom surface within the heat-receiving section along the longitudinal direction.

### (Supplementary Note 8)

The cooling system according to any one of Supplementary notes 1 to 7, in which the cooling region of the heat-receiving section receives heat from a plurality of heat sources.

### (Supplementary Note 9)

The cooling system according to any one of Supplementary notes 2 to 8, in which the cross-sectional shape of the heat-receiving section has a polygonal shape or a composite shape including a linear portion and a curve portion.

### (Supplementary Note 10)

A cooler including:

a heat-receiving section including an approximately constant cross-sectional area along a longitudinal direction in which a length of a cooling region along an arrangement of a heat source is longest, the cooling region cooling the heat source;

a refrigerant which is supplied in a liquid state into the heat-receiving section, is vaporized upon reception of heat, and is recovered from an inside of the heat-receiving section; and

a refrigerant pathway which causes the refrigerant supplied in a liquid state to flow out into the heat-receiving section along the longitudinal direction.

### (Supplementary Note 11)

The cooler according to Supplementary note 10, in which the heat-receiving section comprises the approximately constant cross-sectional area with an approximately constant cross-sectional shape.

### (Supplementary Note 12)

The cooler according to Supplementary note 10 or 11, in which the refrigerant pathway comprises a groove-like portion formed between a first fin and one side surface in the longitudinal direction within the heat-receiving section, the first fin being embedded in a bottom surface within the heat-receiving section along the longitudinal direction, being in close contact with wall surfaces at both ends in the longitudinal direction within the heat-receiving section, and having a uniform height with a gap being opened between the first fin and a ceiling within the heat-receiving section.

### (Supplementary Note 13)

The cooler according to Supplementary note 12, in which the first fin is higher than a liquid level of the refrigerant flowing out into the heat-receiving section.

### (Supplementary Note 14)

The cooler according to Supplementary note 10 or 11, in which the refrigerant pathway comprises a tube which extends in the longitudinal direction, causes the refrigerant to flow in from one end of the heat-receiving section, causes the refrigerant to flow into the heat-receiving section from a plurality of side holes provided at an outer peripheral surface and a leading end hole provided at another end of the heat-receiving section, and is provided at a position apart from a bottom surface within the heat-receiving section.

### (Supplementary Note 15)

The cooler according to any one of Supplementary notes 10 to 14, in which the refrigerant pathway causes the refrigerant to approximately equally flow out into the heat-receiving section along the longitudinal direction.

### (Supplementary Note 16)

The cooler according to any one of Supplementary notes 10 to 15, in which the heat-receiving section comprises a second fin which is embedded in a bottom surface within the heat-receiving section along the longitudinal direction.

### (Supplementary Note 17)

The cooler according to any one of Supplementary notes 10 to 16, in which the cooling region of the heat-receiving section receives heat from a plurality of heat sources.

### (Supplementary Note 18)

The cooler according to any one of Supplementary notes 11 to 17, in which the cross-sectional shape of the heat-receiving section has a polygonal shape or a composite shape including a linear portion and a curve portion.

### (Supplementary Note 19)

A cooling method including:

causing, by a refrigerant pathway, a refrigerant supplied in a liquid state to a heat-receiving section to flow out into the heat-receiving section along a longitudinal direction in which a length of a cooling region along an arrangement of a heat source is longest, the heat-receiving section including an approximately constant cross-sectional area along the longitudinal direction, the cooling region cooling the heat source;

recovering the refrigerant from an inside of the heat-receiving section, the refrigerant being vaporized when the heat-receiving section receives heat; and

cooling the recovered refrigerant and supplying the refrigerant in a liquid state to the heat-receiving section.

### (Supplementary Note 20)

The cooling method according to Supplementary note 19, in which the refrigerant pathway causes the refrigerant to flow out into the heat-receiving section along the longitudinal direction.

### (Supplementary Note 21)

The cooling method according to Supplementary note 19 or 20, in which the heat-receiving section comprises the approximately constant cross-sectional area with an approximately constant cross-sectional shape.

### (Supplementary Note 22)

The cooling method according to Supplementary note 20 or 21, in which the refrigerant pathway comprises a groove-like portion formed between a first fin and one side surface in the longitudinal direction within the heat-receiving section, the first fin being embedded in a bottom surface within the heat-receiving section along the longitudinal direction, being in close contact with wall surfaces at both ends in the longitudinal direction within the heat-receiving section, and having a uniform height with a gap being opened between the first fin and a ceiling within the heat-receiving section.

### (Supplementary Note 23)

The cooling method according to Supplementary note 22, in which the first fin is higher than a liquid level of the refrigerant flowing out into the heat-receiving section.

### (Supplementary Note 24)

The cooling method according to Supplementary note 20 or 21, in which the refrigerant pathway comprises a tube which extends in the longitudinal direction, causes the refrigerant to flow in from one end of the heat-receiving section, causes the refrigerant to flow into the heat-receiving section from a plurality of side holes provided at an outer peripheral surface and a leading end hole provided at another end of the heat-receiving section, and is provided at a position apart from a bottom surface within the heat-receiving section.

### (Supplementary Note 25)

The cooling method according to any one of Supplementary notes 19 to 24, in which the refrigerant is caused to approximately equally flow out into the heat-receiving section along the longitudinal direction.

### (Supplementary Note 26)

The cooling method according to any one of Supplementary notes 19 to 25, in which the heat-receiving section comprises a second fin which is embedded in a bottom surface within the heat-receiving section along the longitudinal direction.

### (Supplementary Note 27)

The cooling method according to any one of Supplementary notes 19 to 26, in which the cooling region of the heat-receiving section receives heat from a plurality of heat sources.

### (Supplementary Note 28)

The cooling method according to any one of Supplementary notes 21 to 27, in which the cross-sectional shape of the heat-receiving section has a polygonal shape or a composite shape including a linear portion and a curve portion.

This application is based upon and claims the benefit of priority from Japanese patent application No. 2016-042492, filed on Mar. 4, 2016, the disclosure of which is incorporated herein in its entirety by reference.

### REFERENCE SIGNS LIST

1, 2 Cooling system
10, 20 Cooling region
11, 21 Heat-receiving section
12, 22 Supply tube
13, 23 Recovery tube
14, 24 Heat radiation section
15 Refrigerant pathway
25 Air cooling fan
26 Heat source
27 First fin
28 Second fin
29 Refrigerant
30 Supply port
31 Recovery port
32 Groove-like portion
33, 33a, 33b, 33c Liquid tube
34, 34a, 34b, 34c Side hole
35, 35a, 35b, 35c Leading end hole
36a Partition

1. A cooling system comprising:
a heat-receiving section including an approximately constant cross-sectional area along a longitudinal direction in which a length of a cooling region along an arrangement of a heat source is longest, the cooling region cooling the heat source;
a supply tube for supplying a refrigerant in a liquid state into the heat-receiving section;
a recovery tube for recovering the refrigerant from an inside of the heat-receiving section, the refrigerant being vaporized upon reception of heat; and
a heat radiation section for cooling the recovered refrigerant and supplying the refrigerant in a liquid state to the supply tube, wherein
the heat-receiving section comprises a refrigerant pathway which causes the refrigerant supplied from the supply tube to flow out into the heat-receiving section along the longitudinal direction.

2. The cooling system according to claim 1,
wherein the heat-receiving section comprises the approximately constant cross-sectional area with an approximately constant cross-sectional shape.

3. The cooling system according to claim 1,
wherein the refrigerant pathway comprises
a groove-like portion formed between a first fin and one side surface in the longitudinal direction within the heat-receiving section,
the first fin being embedded in a bottom surface within the heat-receiving section along the longitudinal direction, being in close contact with wall surfaces at both ends in the longitudinal direction within the heat-receiving section, and having a uniform height with a gap being opened between the first fin and a ceiling within the heat-receiving section.

4. The cooling system according to claim 3,
wherein the first fin is higher than a liquid level of the refrigerant flowing out into the heat-receiving section.

5. The cooling system according to claim 1,
wherein the refrigerant pathway comprises
a tube which extends in the longitudinal direction, causes the refrigerant to flow in from one end of the heat-receiving section, causes the refrigerant to flow into the heat-receiving section from a plurality of side holes provided at an outer peripheral surface and a leading end hole provided at another end of the heat-receiving section, and is provided at a position apart from a bottom surface within the heat-receiving section.

6. The cooling system according to claim 1,
wherein the refrigerant pathway causes the refrigerant to approximately equally flow out into the heat-receiving section along the longitudinal direction.

7. The cooling system according to claim 1,
wherein the heat-receiving section comprises a second fin which is embedded in a bottom surface within the heat-receiving section along the longitudinal direction.

8. The cooling system according to claim 1,
wherein the cooling region of the heat-receiving section receives heat from a plurality of heat sources.

9. The cooling system according to claim 2,
wherein the cross-sectional shape of the heat-receiving section has a polygonal shape or a composite shape including a linear portion and a curve portion.

10. A cooler comprising:
a heat-receiving section including an approximately constant cross-sectional area along a longitudinal direction in which a length of a cooling region along an arrangement of a heat source is longest, the cooling region cooling the heat source;
a refrigerant which is supplied in a liquid state into the heat-receiving section, is vaporized upon reception of heat, and is recovered from an inside of the heat-receiving section; and
a refrigerant pathway which causes the refrigerant supplied in a liquid state to flow out into the heat-receiving section along the longitudinal direction.

11. The cooler according to claim 10, wherein the heat-receiving section comprises the approximately constant cross-sectional area with an approximately constant cross-sectional shape.

12. The cooler according to claim 10,
wherein the refrigerant pathway comprises
a groove-like portion formed between a first fin and one side surface in the longitudinal direction within the heat-receiving section,
the first fin being embedded in a bottom surface within the heat-receiving section along the longitudinal direction, being in close contact with wall surfaces at both ends in the longitudinal direction within the heat-receiving section, and having a uniform height with a gap being opened between the first fin and a ceiling within the heat-receiving section.

13. The cooler according to claim 12,
wherein the first fin is higher than a liquid level of the refrigerant flowing out into the heat-receiving section.

14. The cooler according to claim 10,
wherein the refrigerant pathway comprises
a tube which extends in the longitudinal direction, causes the refrigerant to flow in from one end of the heat-receiving section, causes the refrigerant to flow into the heat-receiving section from a plurality of side holes provided at an outer peripheral surface and a leading end hole provided at another end of the heat-receiving section, and is provided at a position apart from a bottom surface within the heat-receiving section.

15. The cooler according to claim 10,
wherein the refrigerant pathway causes the refrigerant to approximately equally flow out into the heat-receiving section along the longitudinal direction.

16. The cooler according to claim 10,
wherein the heat-receiving section comprises a second fin which is embedded in a bottom surface within the heat-receiving section along the longitudinal direction.

17. The cooler according to claim 10,
wherein the cooling region of the heat-receiving section receives heat from a plurality of heat sources.

18. The cooler according to claim 11,
wherein the cross-sectional shape of the heat-receiving section has a polygonal shape or a composite shape including a linear portion and a curve portion.

19. A cooling method comprising:
causing, by a refrigerant pathway, a refrigerant supplied in a liquid state to a heat-receiving section to flow out into the heat-receiving section along a longitudinal direction in which a length of a cooling region along an arrangement of a heat source is longest, the heat-receiving section including an approximately constant cross-sectional area along the longitudinal direction, the cooling region cooling the heat source;
recovering the refrigerant from an inside of the heat-receiving section, the refrigerant being vaporized when the heat-receiving section receives heat; and
cooling the recovered refrigerant and supplying the refrigerant in a liquid state to the heat-receiving section.

20. The cooling method according to claim 19,
further comprising causing the refrigerant to flow out into the heat-receiving section along the longitudinal direction by the refrigerant pathway.

21-28. (canceled)
